(19) United States
(12) Patent Application Publication
(10) Pub. No.: US 2001/0038129 A1
(43) Pub. Date: Nov. 8, 2001

(54) CMOS transistor semiconductor device

(76) Inventors: Toshihiko Omi, Chiba-shi (JP); Kazutoshi Ishii, Chiba-shi (JP)

Correspondence Address: ADAMS & WILKS, ATTORNEYS AND COUNSELORS AT LAW, 31st FLOOR, 50 BROADWAY, NEW YORK, NY, 10004, US

(21) Appl. No.: 09/833,146

(22) Filed: Apr. 11, 2001

(30) Foreign Application Priority Data
Apr. 19, 2000 (JP) 2000-117964
Apr. 19, 2000 (JP) 2000-117970
Mar. 22, 2001 (JP) 2001-082214

(51) Int. Cl. H01L 29/76; H01L 29/94; H01L 31/062; H01L 31/113; H01L 31/119

(52) U.S. Cl. 257/368

(57) ABSTRACT

There is provided a MOS transistor in which a leak current is suppressed. Impurity regions which have a polarity different from that to drain regions and a higher concentration than that of a well region in the MOS transistor are formed in lower portions of the drain regions in the MOS transistor, so that extension of depletion layers between the drain regions and the well region to a well region side can be suppressed. In particular, since the extension of the depletion layers to the well region side in the lower portions of the drain regions can be suppressed, a large effect is obtained with respect to a suppression of a current flowing through deeper regions than channel regions.

### BACKGROUND OF THE INVENTION

1. Field of the Invention

A semiconductor device constructed by MOS transistors is applied in a wide field, such as to a household equipment, an AV equipment, an information equipment, a communication equipment, and an automobile electrical equipment. Recently, along with the mobility of an electrical equipment, the necessity of a power management IC is rising more than conventionally. The present invention relates to a semiconductor device on which a driver element that can be driven with low consumption power and can supply a large current is mainly mounted.

2. Description of the Related Art

In a MOS transistor used in a semiconductor device, when a length of a gate electrode and a channel length are shortened, a low capacity, a large current drive, and a size saving can be obtained, so that a semiconductor device with a low cost, a high speed operation, and a large circuit can be realized. On the other hand, when a channel length is shortened, it is necessary for a leak current between the drain region and the source region in an off state of the MOS transistor to suppress a current flowing through a region deeper than the channel region in addition to a current flowing through the channel-region. For this current suppression, conventionally, for example, an LDD (Lightly Doped Drain) structure in which a new drain region with a light impurity concentration, is formed in a portion of the drain region near the channel region so as not to largely extend a depletion layer between the drain region and a well region to a well region side, is widely applied to a MOS transistor.

In the case of this LDD structure as shown in FIG. 11A-11D, generally, a drain region 113 with a light impurity concentration is formed after a polysilicon film as a gate electrode 104 and gate insulation film 102 are processed. After that, an insulation film 105 for example an oxide film or the like is deposited by a CVD method, and then processed by etching to form a spacer 106 in side walls of the polysilicon gate electrode. This spacer 106 is formed such that impurity ions do not enter a silicon substrate in a later ion implantation. Then a drain region with a heavy impurity concentration 103 is formed by an ion implantation to form the LDD structure.

However, in a MOS transistor used as a driver element for performing a large current drive if necessary, there is the case where a channel width of about several tens of mm is required. Thus, even when a drain region with a light impurity concentration 113 is formed-in the drain region, as the above LDD structure, there is the case where a leak current cannot be sufficiently suppressed. To prevent this, there is the case where a structure for further suppressing the extension of the depletion layer between the drain region and the well region to the well region side is formed by increasing the impurity concentration of the well region. However, when the impurity concentration of the well region is increased, since an impurity concentration of the channel region is also increased, a characteristic in a subthreshold region of the MOS transistor is deteriorated, so that the leak current flowing through the channel region is increased.

In the LDD structure using the spacer 106, there is a problem with respect to a resistance of the gate electrode by shortening a gate width. Even if an operation speed is improved by shortening the gate width, a transmission speed is reduced by an increase of the resistance in the case where the resistance of the gate electrode is large. In order to reduce the resistance of the gate electrode, for example, the use of a metal silicide with a small resistivity instead of a conventionally used polycrystalline silicon with a high impurity concentration and the formation of low resistance wirings such as aluminum in parallel to the gate electrode are discussed and used. However, even in such cases, the limitation is expected in the state that the width of the gate electrode is 0.3 μm or less.

As a solving method in these cases, there is a method for increasing a radio (aspect ratio) between a height of the gate electrode and a width thereof. By increasing the aspect ratio of the gate electrode, a cross sectional area of the gate electrode is expanded, so that the resistance can be reduced. However, in a conventional LDD structure, the aspect ratio cannot be increased without a limit due to a problem in manufacturing.

This is because the width of the spacer formed by anisotropic etching is depending on the height of the gate electrode. Commonly, the width of the spacer is at least 20% or more of the height of the gate electrode. Thus, in the case where the length of the impurity regions (LDD regions) 13 with a low impurity concentration, as shown in FIG. 2, is set to be 0.1 μm, the height of the gate electrode must set to be 0.5 μm m or less. If the height of the gate electrode is equal to or higher than that, a length of the LDD region is 0.1 μm or more. This leads to an increase of a resistance between a source region and a drain region, and therefore is not desired.

Also, since the width of the spacer is widely varied, characteristics among each transistor are different in many cases. In this matter, the method of manufacturing the LDD structure by the first conventional technique achieves a stability due to a short channel region, and a high integration and a high speed operation. However, from a problem in manufacturing, this method prevents a further high speed operation and a further high integration, and is contradictory.

### SUMMARY OF THE INVENTION

An object of the present invention is to provide a method of suppressing an extension of a depletion layer between a drain region and a well region to a well region side without increasing an impurity concentration of a channel region and making a junction between the drain region and the source region as a shallow junction, and a method of improving a width precision by forming a spacer with a high aspect ratio in an LDD structure.

According to the present invention, there is provided a semiconductor device having a MOS transistor, characterized in that, in a lower portion of a drain region of the MOS transistor, an impurity region which has a polarity different from that of the drain region and a higher impurity concentration than that of a well region of the MOS transistor is formed. Since, in the lower portion of the drain region, the impurity region which has the polarity different from that of the drain region and the-higher impurity concentration than that of the well region of the MOS transistor, is formed, an extension of a depletion layer between the drain region and the well region to the well region side can be suppressed. In particular, since the extension of the depletion layer in the lower portion of the drain region to the well region side can be suppressed, a large effect is obtained with respect to the suppression of a current flowing through a deeper region than channel region.

The impurity region may be formed in not only the lower portion of the drain region but also a lower portion of the source region. Since a region which has the same polarity as that of the well region and a higher impurity concentration than that of the well is formed in the lower portion of the drain region or the source region, the impurity region has a function for stopping a diffusion from the drain region or the source region to a deep side of a well region, so that the drain region or the source region with a shallow junction can be formed. When the drain region and the source region are made as the shallow junction, a current flowing through a deeper region than channel region can be suppressed, so that a larger effect is obtained for a leak current suppression. Also, since the impurity region is formed in only the lower portion of the drain region or the source region, it is not necessary to increase an impurity concentration of the channel region, so that there is no influence on the channel region.

Also, a planar formation portion of the impurity region located in the lower portion of the drain region may be identical to a formation portion of the drain region. Since a process for forming the impurity region located in the lower portion of the drain region can be performed immediately before or after a process for forming the drain region, a new mask process is not required for forming an impurity region located in the lower portion of the drain region. Thus, there is almost no increase in a manufacturing cost for forming the impurity region located in the lower portion of the drain region of course, this is also applied to the case where the impurity region is formed in the lower portion of the source region. Also, when the drain region includes a drain region with a light impurity concentration and a drain region with a heavy impurity concentration as the LDD structure, the impurity region is formed in a lower portion of the light drain region.

The impurity region located in the lower portion of the drain region or the source region has a function for stopping the diffusion from the drain region or the source region to the well region deep side. Thus, when the impurity region is formed by an ion implantation method, it is suitable that an ion implantation depth corresponds to the vicinity of a junction depth of the drain region or the source region after the entire process is completed. When the drain region includes a drain region with a light impurity concentration and a drain region with a heavy impurity concentration as the LDD structure, ions are implanted into the vicinity of the junction depth of the light drain region. Also, although the number of ions to be implanted for forming the impurity region is also dependent on an impurity concentration of the drain region and an impurity concentration of the well region, it is suitable that the number of ions for the impurity region is about several tens of % to the number of ions to be implanted into the drain region.

Also, to solve the above problems, the following means is used in the present invention. That is, a first step of forming an N-type polycrystalline silicon gate in a vicinity of a surface of a P-type semiconductor substrate through a gate insulating film, a second step of introducing an N-type impurity into the P-type semiconductor substrate using the N-type polycrystalline silicon gate as a mask in a self aligning manner to form an N-type impurity region with a low concentration, a third step of oxidizing the N-type polycrystalline silicon gate and a vicinity of the surface of the P-type semiconductor substrate by using a wet thermal oxidation method at a temperature of 700° C. to 800° C. for 10 minutes to 30 minutes to form an oxide film in side wall portions of the N-type polycrystalline silicon gate, and a fourth step of introducing an N-type impurity into the P-type semiconductor substrate using the N-type polycrystalline silicon gate and the oxide film as masks to form an N-type impurity region with a high concentration, are used.

Also, As a method of manufacturing a spacer in an LDD structure, a first step of forming an N-type well region in a vicinity of a surface of a P-type semiconductor substrate and then forming an N-type polycrystalline silicon gate in a vicinity of a surface of an N-type well region through a gate insulating film, a second step of introducing a P-type impurity into the P-type semiconductor substrate using the N-type polycrystalline silicon gate as a mask in a self aligning manner to form a P-type impurity region with a low concentration, a third step of oxidizing the N-type polycrystalline silicon gate and a vicinity of the surface of the N-type well region by using a wet thermal oxidation method at a temperature of 700° C. to 800° C. for 10 minutes to 30 minutes to form an oxide film in the side wall portions of the N-type polycrystalline silicon gate, and a fourth step of introducing a P-type impurity into the P-type semiconductor substrate using the N-type polycrystalline silicon gate and the oxide film as masks to form a P-type impurity region with a high concentration, are used.

Further, after the N-type impurity region with the low concentration is formed, a process for introducing a P-type impurity into a lower side of the N-type impurity region with the low concentration to form an impurity region having a polarity different from that of the drain region in the lower portion of the drain region, is used,

or, after the P-type impurity region with the low concentration is formed, a process for introducing an N-type impurity into a lower side of the P-type impurity region with the low concentration to form an impurity region having a polarity different from that of the drain region in the lower portion of the drain region, is used,

also, the N-type impurity region with the low concentration is formed using a concentration of about 1E18/cm³, and the impurity region located in the lower portion of the drain region is formed using a concentration of about 1E17/cm³,

or, the P-type impurity region with the low concentration is formed using a concentration of about 1E18/cm³, and the impurity region located in the lower portion of the drain region is formed using a concentration of about 1E17/cm³,

so that the MOS transistor with a small leak current can be manufactured.

### BRIEF DESCRIPTION OF THE DRAWINGS

In the accompanying drawings:

FIG. 1 is a cross sectional view of a first embodiment of the present invention;

FIG. 2 is a cross sectional view of a second embodiment of the present invention;

FIG. 3 is a cross sectional view of a third embodiment of the present invention;

FIG. 4 is a cross sectional view of a fourth embodiment of the present invention;

FIG. 5 is a cross sectional view of a fifth embodiment of the present invention;

FIG. 6 is a cross sectional view of a sixth embodiment of the present invention;

FIG. 7 is a cross sectional view of a manufacturing process according to the first embodiment of the present invention;

FIG. 8 is a graph representing a leak current suppression effect according to the first embodiment of the present invention;

FIGS. 9A to 9D are cross sectional views of a seventh embodiment of the present invention;

FIGS. 10A to 10D are cross sectional views of an eighth embodiment of the present invention; and

FIGS. 11A to 11D are cross sectional views of a conventional LDD structure.

### DETAILED DESCRIPTION OF THE PREFERRED EMBODIMENTS

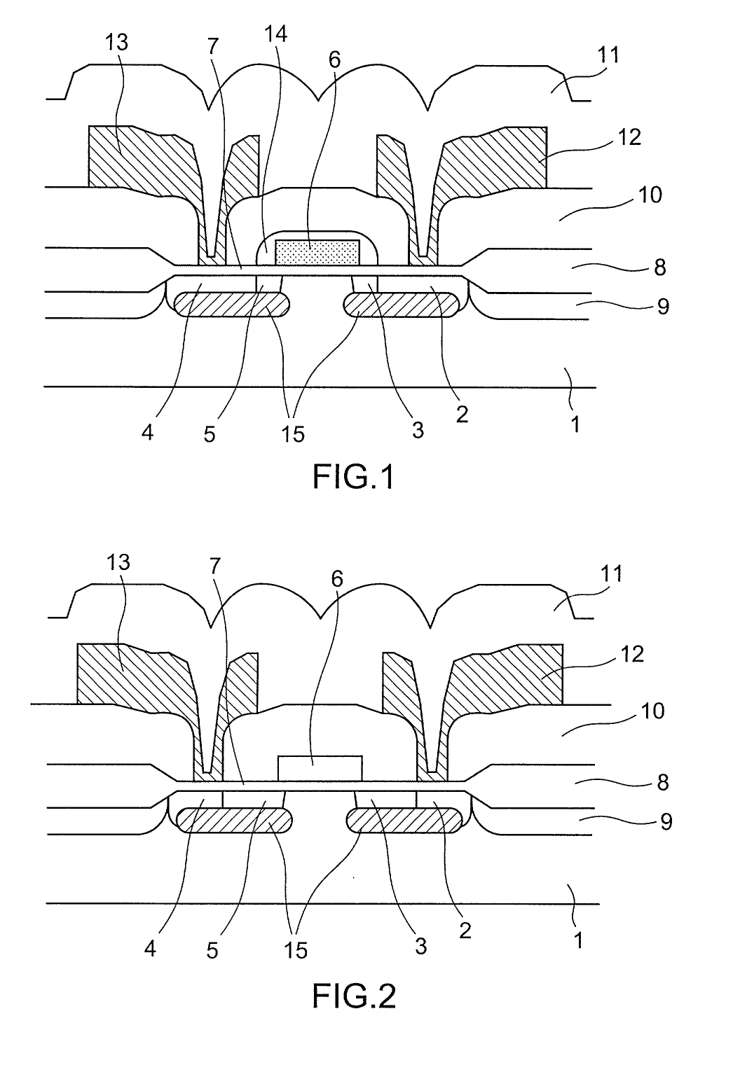

FIG. 1 is a cross sectional view of a MOS transistor according to a first embodiment of the present invention. In this embodiment, impurity regions having a polarity different from that in the drain region and the source region are formed in lower portion of the drain region and the source region in a MOS transistor with an LDD structure. First, a P-channel transistor will be described. A well region 1 is an N-type using phosphorus as an impurity. A field oxide film 8 and a field dope region 9 are formed, and then a gate electrode 6 made of polysilicon is formed on a gate oxide film 7 having a film thickness of 150 angstrom. Then, as shown in FIG. 7, a resist mask in which only the drain region and the source region in the P-channel transistor are opened is formed. Using boron difluoride for forming a light drain region and a light source region, ions are implanted with a self alignment in ion implantation positions 17 and 18 of the drain region and the source region, respectively.

Next, in order to form lower portion impurity regions of the drain region and the source region, phosphorus ions are implanted in ion implantation positions of the impurity regions. At this time, phosphorus ions are implanted with about 150 keV. By the implanted impurity ions, a light drain region 3 and a light source region 5 or impurity regions 15 located in lower portions of the drain region and the source region are formed, after a later process.

A process after this is similar to that for forming a common LDD structure. That, a spacer 14 is formed using a low temperature oxide film, and then a heavy drain region 2 and a heavy source region 4 are formed by an ion implantation using boron difluoride with a self alignment. Further, an interlayer insulating film 10 made of a boron and phosphorus glass film is formed, a drain wiring 12 and a source wiring 13, which are made of an aluminum film is formed, and then a protecting film 11 made of a silicon nitride film is formed. Thus, the P-channel transistor is completed.

Next, an N-channel transistor will be described. A well region 1 is a P-type using boron as an impurity. As in the case of the P-channel transistor, a field oxide film 8, a field dope region 9, a gate oxide film 7 and a gate electrode 6 are formed. Then, a light drain region 3 and a light source region 5 are formed by an implantation of arsenic ions, and impurity regions 15 located in the lower portions of the drain region and the source region are formed by an implantation of boron ions with about 150 keV. A process after this is similar to that for the P-channel transistor. That is, a spacer 14 is formed using a low temperature oxide film, and then a heavy drain region 2 and a heavy source region 4 are formed by an implantation of arsenic ions with a self alignment. Further, an interlayer insulating film 10 made of a boron and phosphorus glass film is formed, a drain wiring 12 and a source wiring 13, which are made of an aluminum film is formed, and then a protecting film 11 made of a silicon nitride film is formed. Thus, the N-channel transistor is completed.

In the description of the above first embodiment, the ion implantation for the impurity regions located in the lower portions of the drain region and the source region is performed after the ion implantation process for forming the light drain region and the light source region. However, even when the ion implantation for forming the light drain region and the light source region is performed after the ion implantation for the impurity regions located in the lower portions of the drain region and the source region is performed, the same effect is obtained.

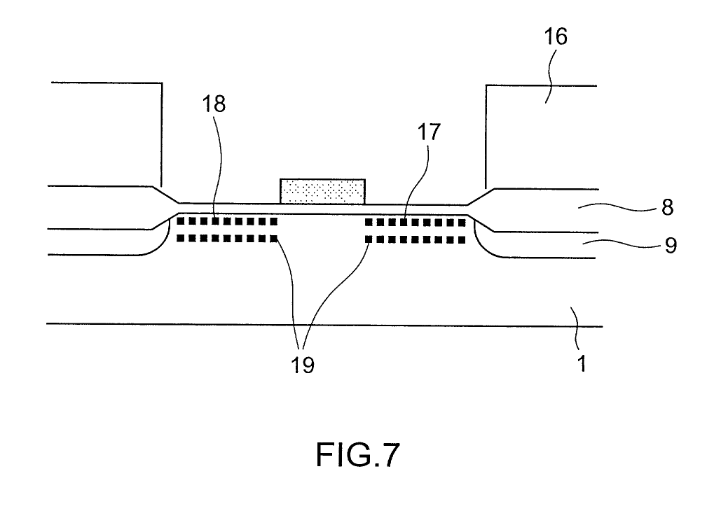

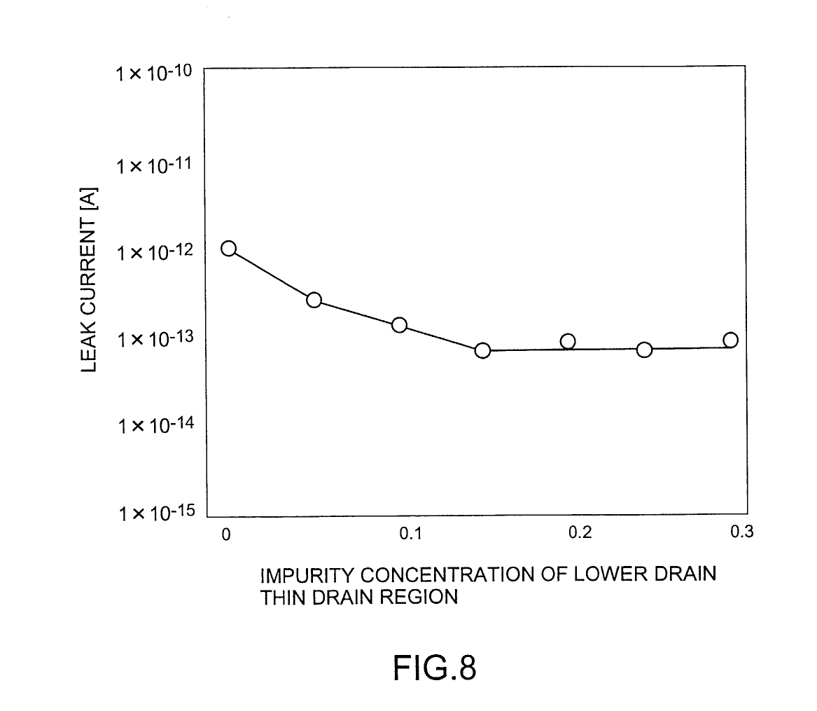

FIG. 8 shows an estimation result with respect to a leak current in the case where a plurality of P-channel transistors are manufactured such that the impurity region located in the lower portion of the drain region in each of the transistors has different impurity concentration. It is apparent that the leak current can be reduced to about ⅓, by the effect of the impurity regions located in the lower portion of the drain region. The same effect is obtained with respect to the N-channel transistor.

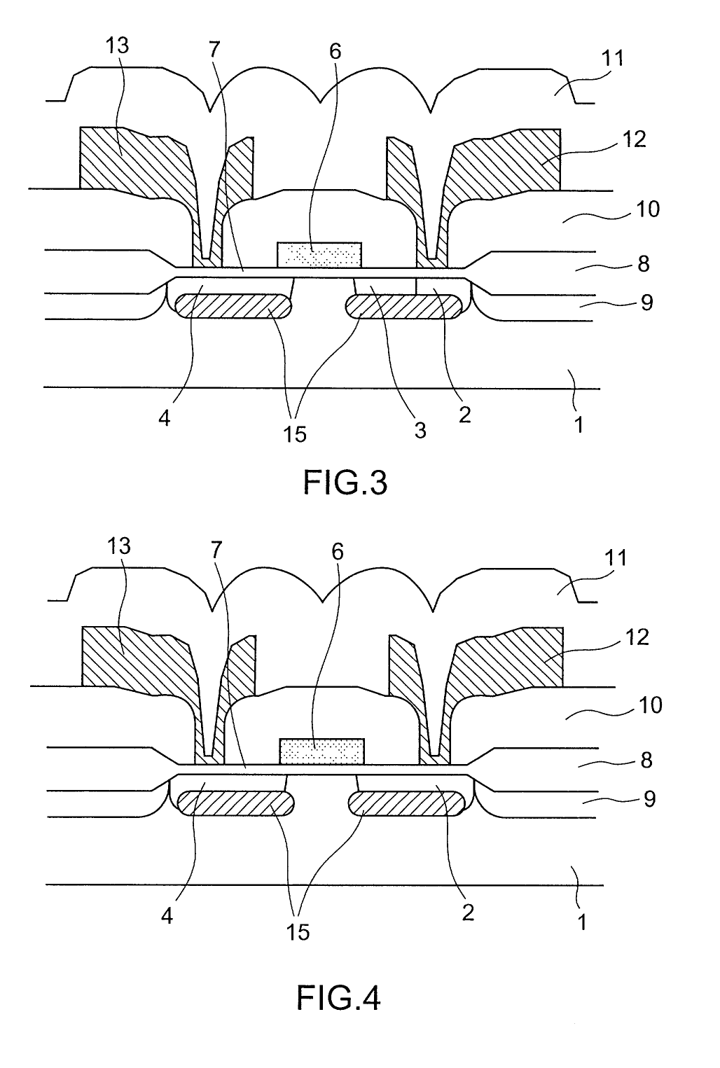

FIGS. 2 and 3 are cross sectional views of MOS transistors according to the second and third embodiments of the present invention. In the second and third embodiments, a light drain region and a light source region are formed by an ion implantation with a self alignment and then a heavy drain region and a heavy source region are formed by an ion implantation with a non self alignment that a region (including a gate electrode) within the distance of about 1 μm from the gate electrode is masked by a resist, so that a transistor with a mask offset structure is completed. Further, in this transistor, impurity regions are formed in the lower portions of the drain region and the source region. FIG. 2 shows a MOS transistor in which both the heavy drain region and the heavy source region are formed apart from the gate electrode with a non self alignment. FIG. 3 shows an example of a MOS transistor in which only the heavy drain region is formed apart from the gate electrode with a non self alignment.

In the case of the P-channel transistor, an N-type well region 1 using phosphorus as an impurity, a field oxide film 8, a field dope region 9, a gate oxide film 7, and a gate electrode 6 are formed. Then, a light drain region 3 and a light source region 5 are formed by an ion implantation using boron difluoride with a self alignment, and successively impurity regions 15 which are located in the lower portions of the drain region and the source region are formed by an implantation of phosphorus ions, using the same resist mask. Next, a heavy drain region 2 and a heavy source region 4 are formed by an ion implantation using boron difluoride with a non self alignment. Further, an interlayer insulating film 10 made of a boron and phosphorus glass film is formed, a drain wiring 12 and a source wiring 13, which are made of an aluminum film is formed, and then a protecting film 11 made of a silicon nitride film is formed. Thus, the P-channel transistor is completed.

In the case of the N-channel transistor, boron is used as an impurity in the well region, arsenic ions are implanted for the source region and the drain region, and boron ion are implanted for the impurity regions located in the lower portions of the source region and the drain region. Except for these, the N-channel transistor is manufactured by the same process as that of the P-channel transistor.

In the second and third embodiments, the ion implantations for the heavy drain region and the heavy source region are performed after the ion implantations for the light drain region, the light source region, and the impurity regions located in the lower portions of the drain region and the source region are performed. However, even when the ion implantations for the light drain region, the light source region, and the impurity regions located in the lower portions of the drain region and the source region are performed after the ion implantations for the heavy drain region and the heavy source region are performed, the same effect is obtained. Also, in those embodiments, the ion implantation for the impurity regions located in the lower portions of the drain region and the source region is performed after the ion implantation process for forming the light drain region and the light source region. However, even when the ion implantation for forming the light drain region and the light source region is performed after the ion implantation for the impurity regions located in the lower portion of the drain region and the source region is performed, the same effect is obtained.

Also, when the light drain region is formed in only the drain region, as in a sixth embodiment of FIG. 6, the impurity regions may be formed in only the lower portion of the drain region.

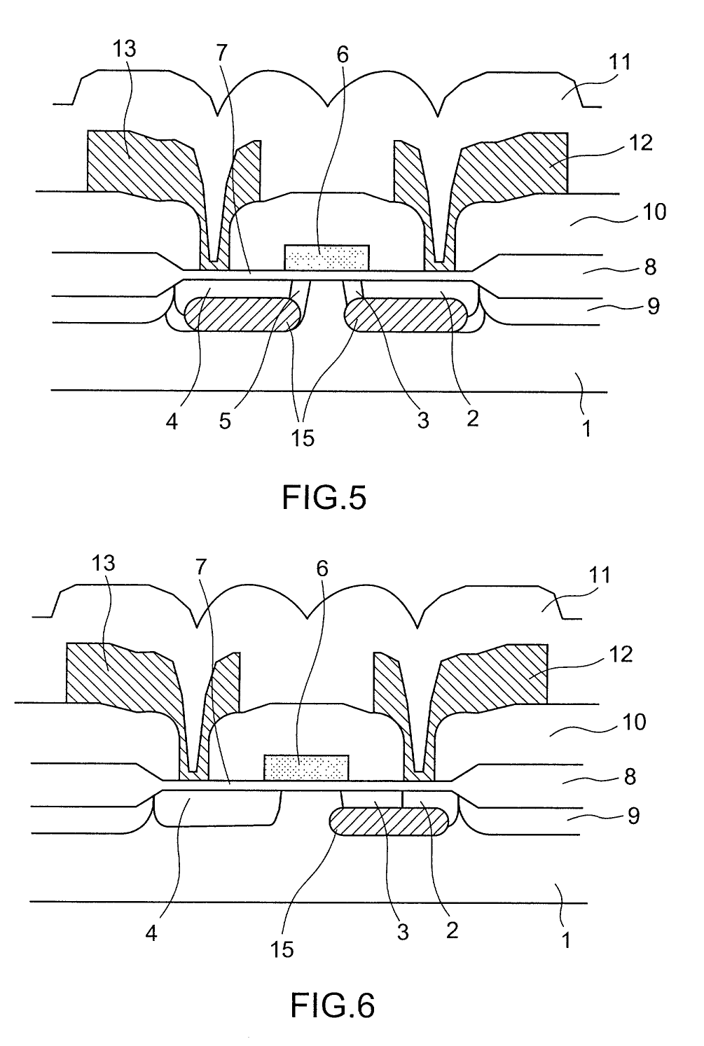

FIGS. 4 and 5 are cross sectional views of MOS transistors according to fourth and fifth embodiments. The fourth embodiment represents a MOS transistor structure with only a heavy drain region and a heavy source region. In this case, after an ion implantation for forming a heavy drain region 2 and a heavy source region 4 is performed, successively using the same resist mask, impurity regions 15 which are located in the lower portions of the drain region and the source region are formed, so that the MOS transistor is manufactured. As in the first embodiment to the third embodiment, in the case of the P-channel transistor, a drain region and a source region are formed by an ion implantation using boron difluoride, and impurity regions which are located in the lower portions of the source region and the drain region are formed by an ion implantation using phosphorus. In the case of the N-channel transistor, a drain region and a source region are formed by an ion implantation using arsenic, and impurity regions located in the lower portions of the source region and the drain region are formed by an ion implantation using boron.

Also, the fifth embodiment represents an embodiment where the present invention is applied to a DDD (Double Doped Drain) structure. In the fourth embodiment, using the same resist mask as that for forming a drain region and a source region in an N-channel transistor, an ion implantation using arsenic for forming heavy regions, an ion implantation using phosphorus for forming light regions, and an ion implantation using boron for forming impurity regions located in the lower portions of the drain region and the source region are performed in succession, so that a MOS transistor is manufactured.

Effects of the present invention can be obtained in the MOS transistors of both FIGS. 4 and 5.

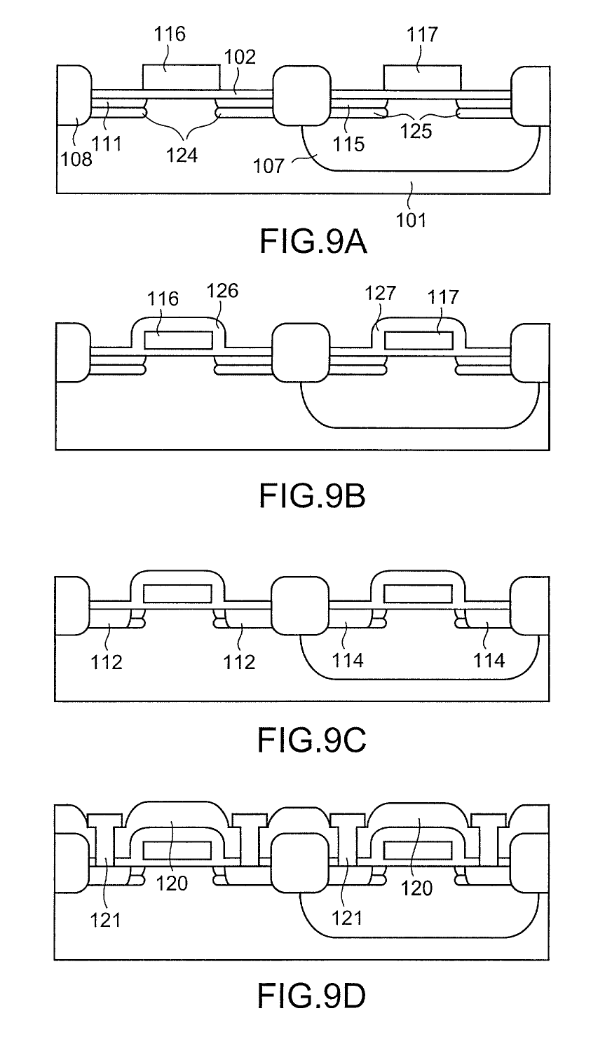

Also, an embodiment for forming a spacer in the LDD structure will be described with reference to FIG. 9. This embodiment represents the case where the present invention is used in a complementary type MOSFET device (CMOS) formed on a single crystalline semiconductor substrate. This embodiment is shown in FIG. 9. First, as shown in FIG. 9(A), an N-type well 107, field insulators 108, N⁻-type impurity regions 111, N⁺-type impurity regions 112, P⁺-type impurity regions 114, P⁻-type impurity regions 115, and gate electrodes 116 (for NMOS) and 117 (for PMOS), which are made of a phosphorus-doped N-type polycrystalline silicon, are formed on a P-type semiconductor substrate 101, using a conventional integrated circuit manufacturing method.

This detailed manufacturing method is as follows. After phosphorus ions are implanted into the vicinity of the surface of the P-type semiconductor substrate 101, annealing is performed at 1000° C. to 1175° C., for 3 hours to 20 hours to diffuse and distribute the phosphorus ions, so that the N-type well 107 having an impurity-concentration of about 1E16 cm⁻³ is formed. Successively, B⁺ ions are implanted into a patterned region and then a channel stopper and the field insulators 108 are formed by a so-called LOCOS method.

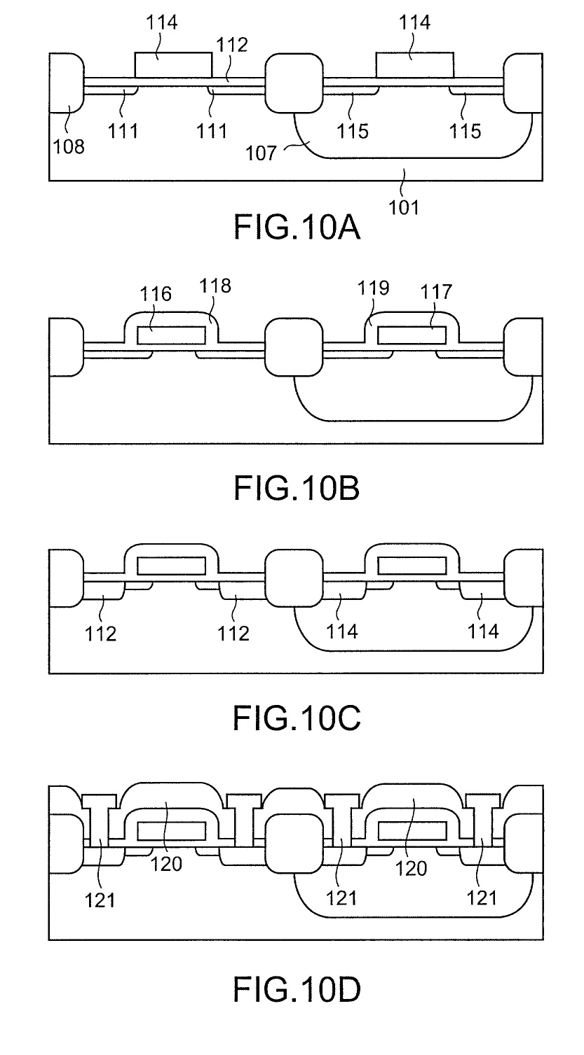

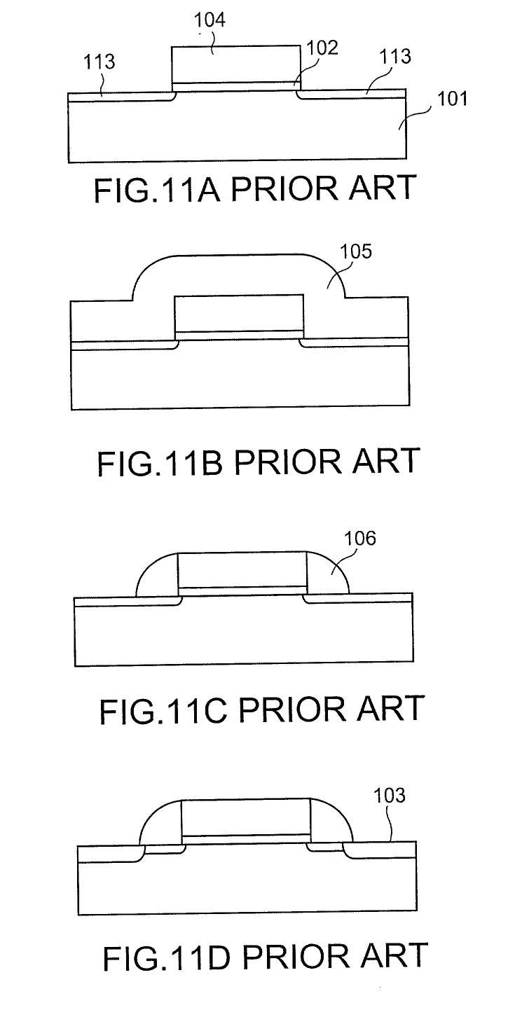

After that, an ion implantation for a threshold voltage control with respect to a desired channel region, a formation of a gate insulating film (silicon oxide) having a thickness of 20 nm to 30 nm by a thermal oxidation method, an ion implantation for a threshold voltage control with respect to other channel regions, a formation of a polycrystalline silicon film having a thickness of 300 nm to 500 nm and a phosphorus concentration of about 1E21 cm⁻³ by a reduced pressure CVD method or the like, and formations of portions 116 and 117 to be used as gate electrodes by patterning this polycrystalline silicon film, are performed. Then, using the portions to be used as gate electrodes and other masks (if necessary), the N⁻-type impurity regions 111 having an impurity concentration of about 1E18 cm⁻³ and an impurity region 124 (located in the lower portion of a drain region) having an impurity concentration of about 1E17 cm⁻³ are formed. Further, BF²⁺ ions are implanted, so that the P⁻-type impurity region 115 having an impurity concentration of about 1E18 cm⁻³ and an impurity region 125 (located in the lower portion of a drain region) having an impurity concentration of about 1E17 cm⁻³ are formed. Thus, the structure of FIG. 10(A) is obtained.

Next, as shown in FIG. 10(B), the portions to be used as gate electrodes are oxidized by a thermal oxidation method (low temperature wet oxidation method). A condition of this oxidation is, for example, in wet oxygen, at about 700° C. to 800° C., and 10 minutes to 30 minutes. In such an oxidation condition, an oxidation rate of a silicon region in which an impurity concentration of N-type is 1E19 cm⁻³ or more is remarkably large. Thus, in this embodiment, the N⁺-type impurity regions 112 and the gate electrodes 116 and 117 made of polycrystalline silicon having a phosphorus concentration of about 1E21 cm⁻³ are oxidized relatively thickly by this thermal oxidation process.

By this thermal oxidation process, oxide films 126 and 127 each having a thickness of about 100 nm to 500 nm are formed around the portions to be used as the gate electrodes to leave the gate electrodes 116 and 117 in the inside. In this oxidation process, silicon surfaces of the portions to be used as the gate electrodes are backed by about 50 nm to 250 nm. On the other hand, the surface of the single crystalline silicon substrate is also backed by about 5 nm to 10 nm. However, since the backed regions are included in the N⁻-type impurity regions 111 or the P⁻-type impurity regions 115, which is extended by the diffusion, this process hardly influences a characteristic of a semiconductor device.

Also, by this oxidation process, since the oxide films 126 and 127 can be formed to become thick at a low temperature in a short time, a change in an impurity concentration profile of a channel region formed in advance is suppressed to be remarkably small. Thus, an amount of an impurity to be implanted in advance can be made small and an impurity profile can be set in only an extreme surface portion of the channel region. As a result, a subthreshold characteristic of a transistor can be suitably kept and lowering of a threshold can be easily realized.

Further, by this oxidation process, since the oxide films 126 and 127 can be formed to become thick at a low temperature in a short time, changes in impurity concentration profiles with respect to the N⁻-type impurity regions 111, the P⁻-type impurity regions 115, and the impurity regions 124 and 125 of the lower portions of the drain regions, which are formed in advance are suppressed to be remarkably small. Thus, this process is also available in shortening an effective channel region length. In particular, in the case of a PMOSFET, B or BF₂ is used as an impurity for forming the P⁻-type impurity regions 115. Also, P or As is used as an impurity for forming the impurity regions 125 of the lower portions of the drain regions (the impurity regions 125 are formed to suppress extensions of depletion layers from the P⁻-type impurity regions 115). However, even if any combination of diffusion coefficients of these impurities is made, the impurities composing the P⁻-type impurity regions 115 are easily largely diffuse. Thus, when a thermal process having a high temperature and a long time is performed, the impurity regions 125 of the lower portions of the drain regions cannot be located under the channel region side end portions of the P⁻-type impurity regions 115. By this, since the depletion layers of the P⁻-type impurity regions 115 are largely extended, a channel leak current is increased, so that shortening of the channel region length is prevented. As a result, it is an essential condition for minuteness to lower a temperature and to shorten a time in a thermal process after the P⁻-type impurity regions 115 and the impurity regions 125 of the lower portions of the drain regions are formed.

Next, the N⁺-type impurity regions 112 and P⁺-type impurity regions 114 are formed again by an ion implantation method. In each of the impurity regions, an impurity concentration is set to be about 1E21 cm⁻³ (FIG. 10(C)).

Finally, a phosphorus glass layer 120 is formed as an interlayer insulating film, as in the case where a conventional integrated circuit is manufactured. This phosphorus glass layer may be formed by using, for example, a reduced pressure CVD method. The phosphorus glass layer is obtained by reaction using monosilane (SiH₄), oxygen (O₂), and phosphine (PH₃) as material gases at 450° C.

After that, holes for electrode formation are formed in the interlayer insulating film to form aluminum electrodes 121. Thus, the complementary type MOS device as shown in FIG. 10(D) is completed.

A MOSFET composing the complementary type MOS device thus obtained has a stable transistor characteristic, a high reliability, and a high performance, in comparison with a MOSFET having a conventional LDD structure using a spacer or a conventional LDD structure using a thermal oxidation.

According to the present invention, impurity regions which have a polarity different from that of drain regions and a higher concentration than that of a well region in the MOS transistor are formed in lower portions of the drain regions in the MOS transistor, so that extension of depletion layers (between the drain regions and the well region) to a well region side is suppressed without setting a high impurity concentration in channel regions, and a junction between the drain region and the source region is made as a shallow junction. Thus, a MOS transistor having a small leak current can be realized. Also, since a new mask process is not required for forming impurity regions located in the lower portions of the drain regions, the manufacturing cost is not increased significantly. Thus, a semiconductor device on which a driver element is mounted that can be manufactured with a low cost, driven at a high speed with a low consumption power, and requires a large current to be driven can be provided.

Also, according to the present invention, an LDD type MOSEFT having a high stability, a high reliability, and a high performance, can be manufactured. The width of an LDD region can also be controlled with extremely high precision within a range of 100 nm to 500 nm. In particular, the present invention is an effective method to realize a high aspect ratio of a gate electrode, in which a future progress is expected, by shortening a channel region.

Of course, a gate electrode with a low aspect ratio in which an aspect ratio is 1 or less, as conventionally, can be used in the present invention. In the present invention, a formation process of an insulating film and an anisotropic etching process of the formed insulating film are not required and the width of an LDD region can be also controlled with high precision, in comparison with a conventional LDD manufacturing method using a spacer. Also, an LDD structure can be formed without changing concentration profiles of various impurity regions formed in advance, in comparison with a conventional LDD manufacturing method using a thermal oxide film. As a result, an effect of the present invention is remarkable.

The present invention is mainly described with respect to a silicon semiconductor device. However, it is apparent that the present invention is also applied to a semiconductor device using other material such as germanium, silicon carbide, or gallium arsenide. Further, in the present invention, an oxidation characteristic of a gate electrode is important as a function. However, a material having a large oxidation rate in a low temperature wet condition, or the like, except for the silicon gate electrode mainly described in the present invention, may be used as the gate electrode. Also, in the embodiments, the process for manufacturing the MOSFET on the P-type semiconductor substrate is described. However, it is apparent that the present invention is also applied to the case where a thin film transistor (TFT) utilizing a polycrystalline or single crystalline semiconductor film formed on an insulating substrate made of quartz, sapphire, or the like is manufactured.

Although the present invention has been described in detail, the present invention is not limited to the above embodiment, but various improvements and modifications may be naturally made in the scope not departing from the gist of the present invention.

What is claimed is:

1. A semiconductor device having a MOS transistor, comprising:
an impurity region which is located in a lower portion of a drain region of the MOS transistor, and which has a polarity different from that of the drain region and a higher impurity concentration than that of a well region of the MOS transistor.

2. A semiconductor device according to claim 1, wherein a planar formation portion of the impurity region is identical to a formation portion of the drain region.

3. A semiconductor device according to claim 1, wherein when a process for forming the impurity region is performed immediately before or after a process for forming the drain region, and when the drain region has a light drain region and a heavy drain region, the process for forming the impurity region is performed immediately before or after a process for forming the light drain region.

4. A semiconductor device according to claim 1, wherein when a process for forming the impurity region is performed by an impurity ion implantation, a depth of an impurity ion to be implanted corresponds to a vicinity of a junction depth of the drain region, and when the drain region has a light drain region and a heavy drain region, the depth of the impurity ion to be implanted corresponds to a vicinity of a junction depth of the light drain region.

5. A semiconductor device according to claim 1, wherein the number of impurity ions in the impurity region is several tens of % to the number of impurity ions in the drain region.

6. A method of manufacturing an insulated gate type semiconductor device, comprising:
a first step of forming an N-type polycrystalline silicon gate in a vicinity of a surface of a P-type semiconductor substrate through a gate insulating film;
a second step of introducing an N-type impurity into the P-type semiconductor substrate using the N-type polycrystalline silicon gate as a mask in a self aligning manner to form an N-type impurity region with a low concentration;
a third step of oxidizing the N-type polycrystalline silicon gate and a vicinity of the surface of the P-type semiconductor substrate by using a wet thermal oxidation method at a temperature of 700° C. to 800° C. for 10 minutes to 30 minutes to form an oxide film in side wall portions of the N-type polycrystalline silicon gate; and
a fourth step of introducing an N-type impurity into the P-type semiconductor substrate using the N-type polycrystalline silicon gate and the oxide film as masks to form an N-type impurity region with a high concentration.

7. A method of manufacturing an insulated gate type semiconductor device according to claim 6, wherein the second step includes the steps of:
introducing a P-type impurity into a portion located under the N-type impurity region with the low concentration after the N-type impurity region with the low concentration is formed; and
forming, in a lower portion of a drain region of the MOS transistor, an impurity region which has a polarity different from that of the drain region and a higher impurity concentration than that of a well region of the MOS transistor.

8. A method of manufacturing an insulated gate type semiconductor device according to claim 6, wherein the second step includes the steps of: forming the N-type impurity region with the low concentration with a concentration of about 1E18/cm³; and forming the impurity region located in the lower portion of the drain region using a concentration of about 1E17/cm³.

9. A method of manufacturing an insulated gate type semiconductor device, comprising:
a first step of forming an N-type well region in a vicinity of a surface of a P-type semiconductor substrate and then forming an N-type polycrystalline silicon gate in a vicinity of a surface of N-type well region through a gate insulating film;
a second step of introducing a P-type impurity into the P-type semiconductor substrate using the N-type polycrystalline silicon gate as a mask in a self aligning manner to form a P-type impurity region with a low concentration;
a third step of oxidizing the N-type polycrystalline silicon gate and a vicinity of the surface of the N-type well region by using a wet thermal oxidation method at 700° C. to 800° C. for 10 minutes to 30 minutes to form an oxide film in side wall portions of the N-type polycrystalline silicon gate; and
a fourth step of introducing a P-type impurity into the P-type semiconductor substrate using the N-type polycrystalline silicon gate and the oxide film as masks to form a P-type impurity region with a high concentration.

10. A method of manufacturing an insulated gate type semiconductor device according to claim 9, wherein the second step includes the steps of:
introducing an N-type impurity into a portion located under the P-type impurity region with the low concentration after the P-type impurity region with the low concentration is formed; and
forming, in a lower portion of a drain region of the MOS transistor, an impurity region which has a polarity different from that of the drain region and a higher impurity concentration than that of a well region of the MOS transistor.

11. A method of manufacturing an insulated gate type semiconductor device according to claim 9, wherein the second step includes the steps of: forming the P-type impurity region with the low concentration using a concentration of about 1E18/cm³; and forming the impurity region located in the lower portion of the drain region using a concentration of about 1E17/cm³.
